(19) United States
(12) Patent Application Publication
(10) Pub. No.: US 2013/0002605 A1
(43) Pub. Date: Jan. 3, 2013

(54) CONTROL DEVICE FOR ENTERING CONTROL COMMANDS INTO AN ELECTRONIC DEVICE

(75) Inventors: Bettina Leuchtenberg, Ehringshausen (DE); Steffen Wildner, Dieburg (DE)

(73) Assignee: Continental Automotive GmbH, Hannover (DE)

(21) Appl. No.: 13/583,423

(22) PCT Filed: Mar. 3, 2011
(86) PCT No.: PCT/EP2011/053194

§ 371 Date: Sep. 7, 2012

(30) Foreign Application Priority Data
Mar. 9, 2010 (DE) 102010010806.5

(51) Int. Cl. G06F 3/041; G06F 3/045

(52) U.S. Cl. 345/174; 345/173

(57) ABSTRACT

A control device for entering control commands into an electronic device. The control device includes a touch screen. Various control menus can be displayed on the touch screen. The touch screen is disposed behind a colored transparent cover and transparent or semitransparent sensors are disposed behind the colored transparent cover adjacent to the touch screen. The sensors are implemented for detecting the presence of an input organ in front of the colored transparent cover. Illuminable symbols and/or illuminable characters are disposed in front of the transparent or semitransparent sensors, and light sources for illuminating the touch screen and the illuminable symbols or characters are present.

### CROSS REFERENCE TO RELATED APPLICATIONS

This is a U.S. national stage of application No. PCT/EP2011/053194, filed on 3 Mar. 2011. Priority is claimed on German Application No.: 10 2010 010 806.5, filed 9 Mar. 2010, the content of which is incorporated here by reference.

### BACKGROUND OF THE INVENTION

1. Field of the Invention

The invention relates to a control device for entering control commands into an electronic device, wherein the control device comprises a touch screen.

2. Description of Prior Art

Devices of this type are known in a large number of applications. Different control menus can be displayed on the touch screen, and can be selected by an input organ, for instance a finger of the operating person. Since the screens of these touch screens have a high resolution, to permit display of the largest possible variety of control menus, the screens are accordingly complex and expensive. The shape of these touch screens is, moreover, usually rectangular. They are often used in motor vehicles to control various items of auxiliary equipment in a vehicle, such as the air conditioning, a radio, or a navigation system. The integration of a touch screen of this sort with other control elements is found to be complex, and to date has only yielded results that bring little aesthetic satisfaction.

### SUMMARY OF THE INVENTION

An object of one embodiment of the invention is a control device with a touch screen that has any desired shape and is easy to operate. This object is achieved in that the touch screen is disposed behind a colored transparent cover and transparent or semitransparent sensors are disposed behind the colored transparent cover adjacent to the touch screen. The sensors are implemented for detecting the presence of an input organ in front of the colored transparent cover, and illuminable symbols and/or illuminable characters are disposed in front of or behind the transparent or semitransparent sensors, and light sources for illuminating the touch screen and the illuminable symbols and/or characters are present.

The colored transparent cover of the touch screen provides a consistent appearance to the touch screen and to the switches disposed adjacent to it in the form of the transparent or semitransparent sensors. The touch screen and the symbols and/or characters are only perceptible when they are appropriately illuminated. One result is that a consistent appearance is achieved. Furthermore, through appropriate lighting, specific symbols and/or characters can be particularly emphasized, and this can be done to designate that they can be selected for operation. Functions that, in the corresponding operating status of the control device, cannot be selected can remain correspondingly unlit, so that only those selections that can in fact be made are offered to a corresponding user of the control device. The colored transparent cover may, moreover, take any desired geometrical form, and can effectively in this way be visually adapted to the corresponding position, for instance in the vehicle. The cover can, for instance, be entirely plane, but it is also, for example, possible for the cover to be formed in such a way that it has two main surfaces that are at a particular angle to one another.

Because the illuminable symbols and/or characters are illuminated according to a status of the control device, it is possible for certain, particularly preferred, operating functions to be emphasized, thus simplifying operation of the control device overall.

Because the sensors are implemented as capacitive switches, a particularly economical solution for the sensors can be realized. These sensors can, moreover, be disposed behind the cover, rendering them insensitive.

If multiple sensors are disposed adjacent to one another and are associated with a single symbol, then more complex switches can be represented. If, for instance, multiple sensors are disposed adjacently in a row and if these are associated with a single symbol, for instance a stylized slide controller or other longitudinal body, then a slide controller can be represented. If the multiple sensors are, for instance, disposed in a circle, then a rotary control can be emulated and a circular or annular symbol is correspondingly disposed above the sensors. By following the circle or ring, an operator can then execute the function of a rotary control. If further symbols are assigned to the symbols just mentioned, then, for instance, by selecting the appropriate further symbol, the function of the symbol with the multiple sensors can be specified. A user can comprehend this particularly intuitively if the further symbols with a single sensor are associated spatially with the symbol that has the multiple sensors. For instance, multiple symbols that are intended to specify the function of the rotary control can be disposed around a symbol that represents a rotary control. The symbol with the multiple sensors can, for instance, represent a rotary control, and the symbols that are arranged around it can, for instance, represent the power of a fan, the volume of the navigation system, the volume of the radio, and the temperature preset for the air conditioning equipment.

If particular menus are associated with particular illuminable symbols and/or characters, and can be displayed on the touch screen after the region of the cover above the corresponding illuminable symbol and/or character has been touched, then it is possible to enter a menu-controllable control function in an easy manner. For instance, a menu for vehicle navigation, the radio, seat positions or other control or information menus can be assigned to each symbol and/or character.

If specific functional settings are assigned directly to particular illuminable symbols and/or characters, these functional settings can be actuated easily, and without repeated operation of the control device.

### BRIEF DESCRIPTION OF THE DRAWINGS

The invention is described in more detail below with reference to the Figures in which:

FIG. 1 is a plan view of a particularly favorable implementation according to one embodiment of the invention, when all the light sources of the control device are switched on;

FIG. 2 is section 2-2 from FIG. 1; and

FIG. 3 is a plan view of the implementation according to FIG. 1 when the colored transparent cover and the illuminable symbols and/or characters have been removed.

### DETAILED DESCRIPTION OF THE PREFERRED EMBODIMENTS

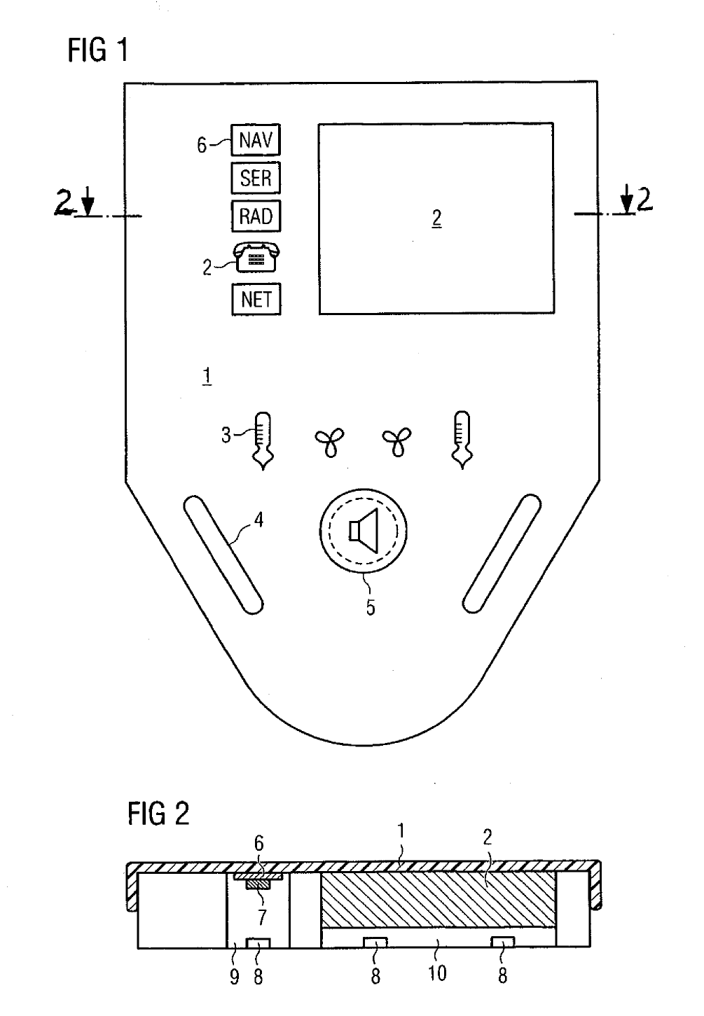

In FIG. 1 a colored transparent cover 1, illuminable symbols 2, 3, 4, 5 and illuminable characters 6 can be seen. Preferably the touch screen comprises a pixel matrix display and a detection device that can detect the presence of an input organ, for instance a finger of an operating person, above the touch screen. This detection can be carried out, for instance, inductively, capacitively, or resistively. Capacitive detection is particularly preferable. The illuminable symbols 2, 3, 4, 5 represent different items. Symbol 2 thus symbolizes a telephone,. symbol 3 symbolizes a thermometer or a fan, symbol 4 represents a slide controller, and symbol 5 symbolically shows a loudspeaker shown inside a circle.

In the section 2-2 shown in FIG. 2, the colored transparent cover 1, the touch screen 2, the illuminable character 6, a transparent sensor 7 for detecting the presence of an input organ, light sources 8 and light boxes 9, 10 can be seen. The illuminable character 6 and the transparent sensor 7 are drawn higher than they are in reality. The illuminable character 6 may be in the form of a printed image of the colored transparent cover. It is also possible to exchange the positions of the transparent sensors and the illuminable characters if the transparency of the sensors is sufficient for the perceptibility of the illuminable character or other illuminable symbols to be ensured. The light sources 8 are disposed inside light boxes 9 and/or 10. The light source in light box 9 thus only illuminates the character 6, and the light sources 8 in light box 10 only illuminate the touch screen 2. In this way, the user can also be optically guided, in that only those input possibilities that can be directly activated are illuminated. It is possible to design the control device such that initially nothing is displayed on the touch screen 2, and no selectable options are offered. On the other hand a menu may be selected by touching the illuminable symbol or the illuminable characters 6. For instance, as is illustrated in FIG. 1, a navigation menu can be selected when the uppermost illuminable character is touched, below that a service menu, below that a radio menu, below that a telephone menu and finally, below that an Internet menu. When the associated symbol or character has been touched, a corresponding menu is displayed on the touch screen and, for instance, only then is the touch screen illuminated. The touch screen can, of course, also be continuously illuminated in order to display other information.

The two symbols 3 on the left are associated with the left-hand symbol 4, the right-hand symbols 3 with the right-hand symbol 4. If the user, for instance, touches the left-hand thermometer 3, he is then able to set a desired temperature for the air conditioning on the left-hand side of a motor vehicle by touching the left-hand symbol 4. By touching the symbolic left-hand fan, it is correspondingly possible by touching the left-hand symbol 4 to regulate the speed of a fan in the left-hand area of the motor vehicle. The same applies to the temperature and the fan on the right-hand side of the motor vehicle, by correspondingly touching the right-hand thermometer or fan, and operating the right-hand symbol 4. In this embodiment, the symbols 3 are associated with symbol 4. By touching symbol 5, the volume of one or more loudspeakers in the motor vehicle can be controlled directly, without the tiresome need to work through control menus first.

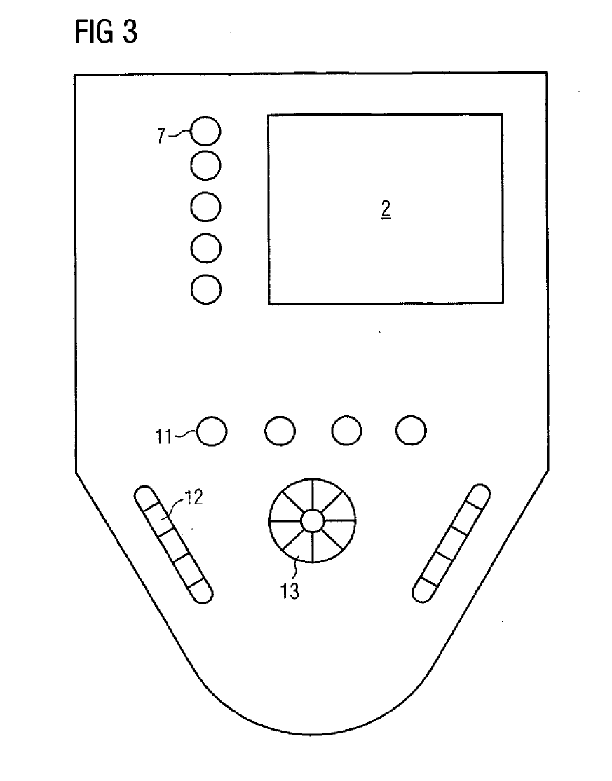

In FIG. 3, in addition to the touch screen 2 and to the transparent sensors 7, further transparent sensors 11, 12, and 13, all of which are formed to detect the presence of an input organ, can be seen. The transparent sensors 7 are located underneath the characters 6 or the symbol 2, the sensors 11 are located underneath the illuminable symbols 3, the sensors 12 are located underneath the illuminable symbols 4, and the sensors 13 are located underneath the illuminable symbol 5. It can be seen that five sensors 12 are respectively disposed adjacent to one another. These five sensors 12 are each associated with a symbol 4 as shown in FIG. 1. It is thus possible to detect the movement of a user's input organ, for instance a finger, along the symbol 4, and in that way emulate a slide controller. The number of five neighboring sensors 12 is only exemplary. It still more sensors are disposed adjacent to one another, the resolution of the movement over the slide controller that is represented can be increased further. It is, of course, also possible to provide fewer sensors. Then, however, the resolution is also correspondingly poorer. Eight sensors 13 are arranged adjacent to one another in a ring, located underneath the symbol 5 from FIG. 1. In this way a rotary controller can be emulated by the movement of an input organ along the circle of the symbol 5, since the movement of the input organ around the circular path is detected by means of the eight sensors 13. An appropriate higher number of sensors can also correspondingly increase the resolution.

The function of the touch screen 2 was not described in more detail, since touch screens in themselves are sufficiently well known from the prior art.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-8. (canceled)

9. A control device for entering control commands into an electronic device, comprising:
a touch screen configured to display various control menus;
a colored transparent cover disposed on a first side of the touch screen;
at least one of a transparent sensor and a semitransparent sensor is disposed behind the colored transparent cover adjacent to the touch screen, wherein the at least one of transparent sensor and semitransparent sensor is configured to detect a presence of an input organ on a second side of the colored transparent cover opposite the first side of the colored transparent cover;
at least one of an illuminable symbol and an illuminable character disposed on a side of the at least one of the transparent sensor and the semitransparent sensor facing the touch screen; and
at least one light source configured to illuminate the at least one of the touch screen and the at least one of the illuminable symbol and the illuminable character.

10. The control device as claimed in claim 9, wherein the at least one of the illuminable symbol and the illuminable character are illuminated based at least in part on a status of the control device.

11. The control device as claimed in claim 9, wherein the at least one of the transparent sensor and the semitransparent sensor is a capacitive switch.

12. The control device as claimed in claim 9, wherein a plurality of at least one of transparent sensors and semitransparent sensors are disposed adjacent to one another, and are associated with a single one of the illuminable symbol and the illuminable character.

13. The control device as claimed in claim 12, wherein a function of the one of the illuminable symbol and the illuminable character with which multiple sensors are associated is selected through a further symbol.

14. The control device as claimed in claim 13, wherein the further symbol is spatially associated with the one of the illuminable symbol and the illuminable character.

15. The control device as claimed in claim 9, wherein a particular menu is associated with a particular one of the one of the illuminable symbol and the illuminable character, and can be displayed on the touch screen after a region of the colored transparent cover corresponding to the one of the illuminable symbol and the illuminable character has been touched.

16. The control device as claimed in claim 9, wherein a specific functional setting is assigned directly to a particular one of the illuminable symbol and the illuminable character.
